(19) United States
(12) Patent Application Publication
(10) Pub. No.: US 2022/0018020 A1
(43) Pub. Date: Jan. 20, 2022

(54) LAMINATED COATING LAYER, METHOD FOR MANUFACTURING SAME, AND METHOD FOR DETERMINING LAMINATED STRUCTURE

(71) Applicant: YAMAGATA UNIVERSITY, Yamagata-shi, Yamagata (JP)

(72) Inventors: Fumihiko HIROSE, Yonezawa-shi, Yamagata (JP); Masanori MIURA, Yonezawa-shi, Yamagata (JP); Kensaku KANOMATA, Yonezawa-shi, Yamagata (JP); Shigeru KUBOTA, Yonezawa-shi, Yamagata (JP); Kazuki YOSHIDA, Yonezawa-shi, Yamagata (JP)

(21) Appl. No.: 17/414,851

(22) PCT Filed: Dec. 16, 2019
(86) PCT No.: PCT/JP2019/049106

§ 371 Date: Jun. 16, 2021

(30) Foreign Application Priority Data
Dec. 17, 2018 (JP) 2018-235833

(51) Int. Cl. C23C 16/40; G01B 11/06; C23C 16/455; C09D 133/12; C09D 5/00; C09D 5/08

(52) U.S. Cl. CPC C23C 16/40; G01B 11/0641; C23C 16/45527; G01J 4/04; C09D 5/002; C09D 5/08; C09D 133/12

(57) ABSTRACT

The disclosed laminated coating layer includes a metal oxide film formed on a processing target through low-temperature atomic layer deposition. The coating layer includes at least one set of at least two layers of an adhesion layer, a moisture-proof layer, and a waterproof layer, stacked from the surface of the processing target in this order. The adhesion layer is formed of at least one film selected from a metal oxide film and a resin film; the moisture-proof layer is a film containing alumina as a predominant ingredient; and the waterproof layer is formed of at least one film of a resin film and a metal oxide film which is selected from among a silica film, a niobium oxide film, and a zirconium oxide film.

### TECHNICAL FIELD

The present invention relates to a method for forming a protective film for providing electronic components, metallic components, and resin components with corrosion resistance and moisture-proof performance, and to a method for evaluating the protective film.

### BACKGROUND ART

Precision components and vacuum components need to ensure extended service life through provision of an anti-corrosive coating film thereon. In these components, members made of aluminum, stainless steel, etc. are used. These members must be protected from corrosion and rusting, which would otherwise be caused by acidic or alkaline solution and corrosive gas (e.g., halogen), through coating with a metal oxide film. In electronic components such as a discrete-type transistor and a diode, semiconductor chips are encapsulated with a resin and wired with lead wires. Such semiconductor electronic components must be protected from oxidation of semiconductor parts and lead wires due to invasion of moisture.

Not only in semiconductor devices but also in electronic components such as a capacitor and an inductor, the characteristics of resistors included therein are problematically deteriorated through water-induced oxidation. Thus, the surfaces of the components are required to have moisture-proof performance. Meanwhile, optical components such as lenses are often formed from a resin material. Such optical components need to ensure extended service life by suppressing penetration of water or oxygen to thereby inhibit hazing.

In order to attain such protection, a metal oxide coating film is essentially provided. However, since a majority of such electronic components, resin components, and precision components cannot withstand high temperatures, a limitation is imposed on the applicable coating technique. Further, in organic electronics, which have been rapidly developed in recent years, electronic circuits formed of organic semiconductor parts and resistors are arranged on a resin film, and such electronic circuits are also required to have corrosion resistance and moisture-proof performance. Needless to say, such a coating film must be provided through a room-temperature process without heating.

There have been proposed various techniques for forming coating films of metal oxides such as SiO₂, Al₂O₃, ZrO₂, and TiO₂. One technique for depositing metal oxide film is thermal spraying. In thermal spraying, metal oxide particles are heated to form particles in a quasi-molten state, and the hot particles are sprayed to an object, to thereby form a metal oxide coating. Since the method is based on spraying high-temperature particles, difficulty is encountered in spraying the particles uniformly onto outer surfaces of target components having complex shapes. In addition, since the temperature of such a target component rises due to high-temperature sprayed particles, difficulty is encountered in applying the particles to components containing a resin which deforms by heat. Also, thermal spraying per se is suited for forming a thick coating film having a thickness of 0.1 mm to 1 mm. Thus, when the method is applied to a container having a minute structure such as flanges, dimensional errors may problematically occur after application.

For coating the surface of a vacuum component or a metal pipe with a metal oxide film, a chemical vapor deposition (CVD) technique is employed. In CVD, a processing target is placed in a vacuum container, and a metal oxide to be formed is, for example, Al₂O₃, SiO₂, or TiO₂. The metal oxide film is formed by use of an organometallic gas as a source gas. For example, Al₂O₃ is formed from trimethylaluminum; TiO₂ is formed from titanium tetraisopropoxide or tetrakis(dimethylamino)titanium; and SiO₂ is formed from tridimethylaminosilane. The organometallic gas and an oxidizing gas (e.g., oxygen) are fed to the vacuum container, and a processing target is heated at a high temperature of some hundreds of degree (° C.), to thereby form a metal oxide coating film. However, since the technique also requires a heating process, difficulty is encountered in application of the technique to electronic components having a minute structure which deforms by variation in temperature, and to components containing resin parts.

For forming a metal oxide film at low temperature, sputtering is employed as a film formation technique. In the sputtering method, argon plasma is generated in a vacuum container, and a source metal is irradiated with ions in the plasma. The collided source metal species is oxidized in an oxygen atmosphere, to thereby deposit a corresponding metal oxide on a target object. Although the technique enables formation of a thin film at room temperature, difficulty is encountered in sufficiently covering a cavity-like portion of a component having a complex surface shape.

For coating the surface of an electronic component with a metal oxide film, atomic layer deposition is also employed as a film formation technique other than CVD. For example, Patent Document 1 discloses a method for forming an oxide thin film on a solid substrate. Specifically, the method is a thin film deposition method characterized by including, sequentially, a step of placing a solid substrate in a reaction container, maintaining the temperature of the solid substrate to be higher than 0° C. and 150° C. or lower (preferably 100° C. or lower), and filling the reaction container with an organometallic gas (e.g., trimethylaminosilane, bisdimethylaminosilane, or methylethylaminohafnium); a step of exhausting the atmosphere of the reaction container or filling the container with an inert gas (e.g., nitrogen, argon, or helium); a step of feeding an oxidizing gas having an enhanced activity (e.g., plasma-state water vapor or oxygen); and a step of exhausting the atmosphere of the reaction container or filling the container with an inert gas (e.g., nitrogen, argon, or helium), wherein the set of the steps is repeated. Patent Document 1 also discloses an embodiment of the method, in which a processing target solid is placed in a vacuum container without heating, to thereby form silica (i.e., an inorganic oxide) on the target solid at room temperature.

However, in order to form an anti-corrosive dense film through the above technique, there is needed a specifically designed film structure in which the film is closely attached to a substrate thereunder for avoiding defoliation thereof and accumulation of strain of a component film. In other words, close adhesion must be secured by modifying the surface structure and wettability of the substrate thereunder. Meanwhile, as disclosed in Non-Patent Document 1, an alumina (Al₂O₃) film is generally employed as an anti-corrosive, moisture-proof film. When the film thickness is in excess of 100 nm, the alumina film per se is hard and non-flexible. In this case, problematic defoliation occurs. In addition, since the alumina film deliquesces in the presence of water, the as-formed film is unstable under high-temperature/moisture conditions, which is problematic. Thus, there has not been clearly elucidated a film structure including a metal oxide film formed at room temperature, which structure ensures close film adhesion and avoids deliquescence in the presence of water.

The same situation is involved in the case where moisture-proof performance is attained through the aforementioned technique. More specifically, although alumina provides an anti-corrosive film which suitably suppresses permeation of water vapor, an adhesion layer serving as an appropriate underlayer must be provided in order to fully attain the performance. Also, a waterproof film must be disposed to inhibit deliquescence in the presence of water.

In order to solve the aforementioned problems, a functional film having an optimum film structure is employed. However, currently, there exists no method for appropriately determining whether or not the film has been designed as intended.

Generally, the structure of an oxide film is analyzed through spectroscopic ellipsometry. In this method, an analysis target is irradiated with S-polarized light and P-polarized light with the same amplitude. The ratio in intensity of the reflected S-polarized light to the reflected P-polarized light is represented by tan ψ, and the phase difference between the reflected S-polarized light and the reflected P-polarized light is represented by Δ. ψ and Δ are measured within an appropriate range of wavelength, and the results are expressed as a spectrum. On the basis of a structure (model) postulated in advance, theoretical values of ψ and Δ are calculated. An inspector visually checks matching of a measured value with a corresponding theoretical value. While the model is modified, a model which can match measured values of V and A with theoretical values of V and A is determined. The film structure of the analysis target is estimated on the basis of the determined model.

However, such a film structure is estimated depending absolutely on a manual operation of the inspector, and there has existed no technique which can automatically determine the optimized structure.

### PRIOR ART DOCUMENTS

### Patent Documents

Patent Document 1: Japanese Patent Application Laid-Open (kokai) No. 2013-11476

### Non-Patent Documents

Non-Patent Document 1: Japanese Journal of Applied Physics, Vol. 86, No. 9, pp. 796-800, 2017

### SUMMARY OF THE INVENTION

### Problems to be Solved by the Invention

An object of the present invention is to provide a laminated coating layer having corrosion resistance and moisture-proof performance by forming films having corrosion resistance and moisture-proof performance on an electronic component through room-temperature atomic layer deposition. Another object is to provide a method for simply determining whether or not the laminated coating layer is appropriate.

### Means for Solving the Problems

In one mode of the present invention to attain the aforementioned objects, there is provided a laminated coating layer, which is a coating layer including a metal oxide film formed on a processing target through low-temperature atomic layer deposition, wherein the coating layer comprises at least one set of at least two layers of an adhesion layer, a moisture-proof layer, and a waterproof layer, stacked from the surface of the processing target in this order; the adhesion layer is formed of at least one film selected from a metal oxide film and a resin film; the moisture-proof layer is a film containing alumina as a predominant ingredient; and the waterproof layer is formed of at least one film of a resin film and a metal oxide film which is selected from among a silica film, a niobium oxide film, and a zirconium oxide film.

In one preferred embodiment, the surface of the processing target is a hydrophilic surface, and the adhesion layer is formed of a silica film.

In another preferred embodiment, the surface of the processing target is a non-flat surface, and the adhesion layer is formed of the resin film.

Preferably, the moisture-proof layer is a single layer of an alumina film having a thickness of 50 nm or less, or includes a structure in which an alumina film having a thickness of 50 nm or less and a strain-relaxing film are alternatingly and multiply stacked.

Preferably, the strain-relaxing film is a film containing an oxide of a metal other than Group III metals, a film containing carbon as an impurity, or a resin film.

In another mode of the present invention, there is provided a method for forming the laminated coating layer of the above-described mode, the method comprising providing a vacuum container having a process container for accommodating a processing target; connecting, to the vacuum container, an exhaust means which can discharge the gas in the process container, an organometallic gas introduction means for introducing an organometallic gas into the process container and filling the container with the organometallic gas, and an excited and humidified gas introduction means for introducing an excited and humidified gas into the process container and filling the container with the excited and humidified gas;

conducting the steps (1) to (4):
(1) a step of introducing the organometallic gas to the processing target through the organometallic gas introduction means;

(2) a step of discharging an organometallic gas surrounding the processing target through the exhaust means;

(3) a step of introducing the excited and humidified gas to the processing target through the excited and humidified gas introduction means; and

(4) a step of discharging the humidified gas surrounding the processing target through the exhaust means; and

repeating the steps (1) to (4), to thereby form the metal oxide film.

In still another mode of the present invention, there is provided a method for determining a lamination structure, the method comprising irradiating the surface of a substrate provided with the laminated coating layer with S-polarized light and P-polarized light with the same amplitude; measuring the ratio in intensity of the reflected S-polarized light to the reflected P-polarized light, represented by tan ψ, and the phase difference between the reflected S-polarized light and the reflected P-polarized light, represented by Δ, within a range of 300 to 800 nm, to thereby obtain ψ₁ and Δ₁; calculating theoretical values of ψ₂ and Δ₂ within a range of 300 to 800 nm through a matrix method on the basis of a postulated lamination structure with a variable d_{A} corresponding to the thickness of the moisture-proof layer; defining a function ϕ:

$$\begin{matrix}[ NF 1 ] & \\ ϕ = min χ ( {d}_{A} ) & ( 1 ) \\ χ ( {d}_{A} ) = {\frac{1}{\sqrt{2 M}} [ {\sum }_{i = 1}^{M} \{ {( {Δ}_{1} ( {λ}_{i} , {d}_{A} ) - {Δ}_{2} ( {λ}_{i} ) )}^{2} + {( {Ψ}_{1} ( {λ}_{i} , {d}_{A} ) - {Ψ}_{2} ( {λ}_{i} ) )}^{2} \} ]}^{1 / 2} & ( 2 )\end{matrix}$$

(wherein formula (1) is an equation for obtaining a minimum value of formula (2) with variation of d_{A}; M represents the number of points of measuring; and Xi is a wavelength of 300 nm to 800 nm in the calculation) as a function which can assess a matching degree between a measured value and a calculated value; and determining a threshold value by means of the function ϕ representing the matching degree, to thereby determine whether or not the laminated coating layer of the substrate has the postulated lamination structure.

### Effects of the Invention

The present invention can provide a laminated coating layer serving as a protective film for providing electronic components and resin components with corrosion resistance, and a method for forming the laminated coating layer. The invention can indicate a film structure for optimizing the effects. As a result, corrosion resistance can be effectively enhanced.

Also, the present invention can provide a laminated coating layer determination method for simply determining whether the laminated coating layer has an appropriate film structure.

### BRIEF DESCRIPTION OF THE DRAWINGS

FIG. 1 A schematic structure of a coating film according to an embodiment of the present invention.

FIG. 2 A cross-sectional TEM image and a model structure of the coating film as an example of the present invention.

FIG. 3 A cross-sectional TEM image of a coating film as a comparative example of the present invention, which is an alumina single layer (20 nm) formed on a SUS430 substrate through room-temperature atomic layer deposition.

FIG. 4 Results of concentrated hydrochloric acid corrosion test of alumina film (about 70 nm) formed on a metallic aluminum substrate, in the cases of alternating stacking of alumina layers and carbon-containing alumina layers (an example of the present invention), and alumina single-layer film.

FIG. 5 Results of corrosion test (immersion in concentrated hydrochloric acid for 60 seconds) of an alumina layer (moisture-proof layer)-coated galvanized plate, in the cases of presence of a PMMA (acrylic resin film) serving as an adhesion layer (an example of the invention) and absence thereof.

FIG. 6 Results of concentrated hydrochloric acid corrosion test of alumina single film (30 nm) formed on a S304 substrate, in the cases of presence of a strain-relaxing layer of PMMA (an example of the invention) and absence thereof (at the same alumina layer thickness).

FIG. 7 Results of concentrated hydrochloric acid corrosion test of an alumina moisture-proof layer formed on a SUS304 substrate, in the cases of presence of a waterproof layer of niobium oxide (an example of the invention) and absence thereof.

### MODES FOR CARRYING OUT THE INVENTION

Next will be described a technique of low-temperature atomic layer deposition, which can provide the laminated coating layer of the present invention. As used herein, the term “low-temperature atomic layer deposition” refers to a technique of an atomic layer deposition process which can form a metal oxide film at a low temperature higher than 0° C. and 150° C. or lower, preferably 100° C. or lower, more preferably room temperature (about 15° C. to about 35° C.). A specific procedure is as follows.

Firstly, a vacuum container having a process container which can accommodate a processing target is provided. The vacuum container has an exhaust means which can discharge the gas in the process container, an organometallic gas introduction means for introducing an organometallic gas into the process container and filling the container with the organometallic gas, and an excited and humidified gas introduction means for introducing an excited and humidified gas into the process container and filling the container with the excited and humidified gas. There are conducted the following steps (1) to (4):

(1) a step of introducing the organometallic gas into the process container through the organometallic gas introduction means;

(2) a step of discharging an organometallic gas in the process container through the exhaust means;

(3) a step of introducing the excited and humidified gas into the process container through the humidified gas introduction means; and

(4) a step of discharging the humidified gas in the process container through the exhaust means. The steps (1) to (4) are repeatedly conducted, to thereby form a metal oxide film on the surface of the processing target.

In the above procedure, preferably, an inert gas introduction means is connected for introducing an inert gas into the process container and filling the container with the inert gas. While carrying out step (2), the inert gas is preferably introduced into the process container through the inert gas introduction means, and while carrying out step (4), the inert gas is preferably introduced into the process container through the inert gas introduction means. Through introduction of the inert gas, the organometallic gas is completely substituted by the inert gas in step (3). Therefore, a film formed by introducing a humidified gas has a small residue content.

In a preferred embodiment of the excited and humidified gas introduction means, argon or helium to which water vapor has been added is transferred to a glass tube, and a high-frequency magnetic field is applied through the glass tube to the gas, to thereby generate plasma in the glass tube. As a result, the humidified gas is excited by the plasma, and the excited humidified gas is introduced to the process container. By virtue of the excited and humidified gas introduction means, the exited humidified gas can be readily supplied.

In step (3), desirably, organometallic gas molecules adsorbed on the surface of the processing target are oxidized and decomposed, to thereby form a metal oxide and provide the surface with adsorption sites. This procedure effectively and consistently ensures a substantial film thickness.

In the case of forming Al₂O₃ film, an organic aluminum compound such as trimethylaluminum is used as an organometallic gas. However, aluminum chloride is not suitable, since it generates corrosive hydrogen chloride gas during a room-temperature atomic layer deposition process. Specifically, when a metallic electronic component is coated with such an alumina film, the target is damaged by corrosion. In the case of forming silica, an organoaminosilicon such as tetrakis(amino)silicon is suitably used. In the case of forming titanium oxide, an organoaminotitanium such as tetrakis(dimethylamino)titanium is suitably used. In the case of forming zirconiumoxide film, an organoaminozirconium such as tetrakis(ethylmethylamino)zirconium is suitably used. When niobium oxide is used, tert-butylimidotris(ethylmethylamido)niobium is suited as an organic aminoniobium compound.

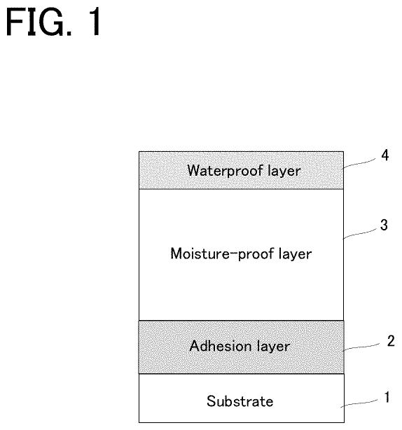

The laminated coating layer of the present invention has a lamination structure including a metal oxide film formed through low-temperature atomic layer deposition. With reference to FIG. 1, the lamination structure will be described in detail.

As shown in FIG. 1, the laminated coating layer is provided on a substrate 1, which is exemplified as a processing target, and includes an adhesion layer 2 for closely bonding to the substrate 1, a moisture-proof layer 3 which is formed thereon and which inhibits passage of ambient water vapor, and a waterproof layer 4 which is formed on the moisture-proof layer 3 and which prevents deliquescence due to the moisture of the moisture-proof layer.

FIG. 1 shows a 3-layer structure including the adhesion layer 2, the moisture-proof layer 3, and the waterproof layer 4, which is a most preferred structure. However, in accordance with the purpose of use or the level of a target corrosion resistance, two layers may be selected from among the adhesion layer 2, the moisture-proof layer 3, and the waterproof layer 4 to form the structure.

When the base layer is a metal layer coated with a hydrophilic oxide layer, the adhesion layer 2 for the base layer is suitably formed of a metal oxide film hydrophilic per se (e.g., titanium oxide) or silica. By providing the adhesion layer, hydroxyl groups present on the water-contact surface of the base layer form chemical bonds with the adhesion layer 2, to thereby enhance interlayer bonding. When the substrate is made of a raw member having cracks, pits, and microparticles on the surface, a resin film is suited for the adhesion layer 2, since the resin film is formed through a coating process effective for leveling the surface. In the case of atomic layer deposition, when the surface of the substrate has quasi-nanometer-size holes or cracks or adsorbed microparticles, the formed film suffers from generation of defects. In this case, defoliation may occur, resulting in deterioration in corrosion resistance and moisture-proof performance. When a resin film is disposed on a surface having nanometer-order irregularities through a coating process, the surface can effectively level. As a result, defoliation of the moisture-proof layer 3 and the waterproof layer 4 provided on the resin film is prevented. Poly(methyl methacrylate) film (PMMA film) or polyimide film may be employed as the resin film.

The moisture-proof layer 3 is preferably a layer containing alumina as a predominant ingredient and is formed through the aforementioned low-temperature atomic layer deposition. Generally, when an alumina film is formed through room-temperature atomic layer deposition, thin films each having a thickness of about 0.1 nm are repeatedly stacked. In the course of the stacking process, reactants remaining in the films are released, to thereby cause shrinkage of the films. Thus, the films are subjected to strain, resulting in defoliation. Meanwhile, when a metal oxide coating film receives a change in temperature of about 200° C., defoliation occurs between the substrate 1 and the moisture-proof layer 3 due to the difference in thermal expansion coefficient. The defoliation is aggravated, when the thickness of the moisture-proof layer exceeds 50 to 100 nm. Thus, the layer thickness must be adjusted to a value thereunder. When the thickness of the moisture-proof layer 3 increases, penetration of water vapor is expected to be suppressed commensurate with the increase in thickness. However, when the layer thickness exceeds the above level, vapor penetration is activated by occurrence of problematic defoliation. Therefore, if the layer thickness is modified to a level higher than the upper limit, a multilayer structure in which alumina layers and strain-relaxing layers are repeatedly stacked is desirably employed. As the strain-relaxing layer, a film whose density has been reduced by incorporating a carbon impurity into alumina, or a Group IV metal oxide film is preferred. Examples of the Group IV metal include titanium, zirconium, and hafnium. These are tetravalent metals, and films of a tetravalent metal oxide such as titanium oxide, zirconium oxide, or hafnium oxide are preferred. Aluminum contained in alumina is a trivalent metal, and the crystal structure of alumina differs from that of a tetravalent metal oxide. Thus, alumina suppresses propagation of strain in a film to the upper layer.

The waterproof layer 4 is suitably formed of an oxide which is less likely to undergo deliquescence in the presence of water. Examples of suitable metal oxides include SiO₂, zirconium oxide, and niobium oxide. The waterproof layer inhibits deliquescence of alumina film serving as the moisture-proof layer 3, thereby effectively preventing deterioration in the moisture-proof performance of alumina film under wet conditions.

The aforementioned lamination structure is assessed through the following procedure. The analysis target is a 3-layer structure provided on a metal substrate, the structure including a titanium oxide film formed on the metal substrate and serving as the adhesion layer 2, an Al₂O₃ film serving as the moisture-proof layer 3, and an SiO₂ surface film serving as the waterproof layer 4. Next will be described a method for determining a layer structure including the adhesion layer 2 (titanium oxide, 3 nm to 5 nm), the moisture-proof layer 3 (alumina layer, 10 nm to 100 nm), and the waterproof layer 4 (SiO₂, 3 nm to 10 nm).

Detection of the 3-layer structure is performed through spectroscopic ellipsometry. Specifically, the surface of an analysis target is irradiated with S-polarized light and P-polarized light with the same amplitude at an incident angle of 75° with respect to the normal line of the sample surface. The ratio in intensity of the reflected S-polarized light to the reflected P-polarized light, represented by tan ψ, and the phase difference between the reflected S-polarized light and the reflected P-polarized light, represented by Δ, are measured, within a range of 300 to 800 nm, to thereby obtain ψ₁ and Δ₁. Theoretical values of ψ₂ and Δ₂ are calculated within a range of 300 to 800 nm through a matrix method on the basis of a postulated 3-layer structure with a variable d_{A} corresponding to the thickness of the alumina film. The following function ϕ is defined as a function which can assess a matching degree between a measured value and a calculated value.

$$\begin{matrix}[ NF 2 ] & \\ ϕ = min χ ( {d}_{A} ) & ( 1 ) \\ χ ( {d}_{A} ) = {\frac{1}{\sqrt{2 M}} [ {\sum }_{i = 1}^{M} \{ {( {Δ}_{1} ( {λ}_{i} , {d}_{A} ) - {Δ}_{2} ( {λ}_{i} ) )}^{2} + {( {Ψ}_{1} ( {λ}_{i} , {d}_{A} ) - {Ψ}_{2} ( {λ}_{i} ) )}^{2} \} ]}^{1 / 2} & ( 2 )\end{matrix}$$

The function ϕ is an equation for obtaining a minimum value of formula (2) with variation (parameter) d_{A}. In the calculation, the wavelength λ₁ is set to 300 nm to 800 nm, and the intervals of adjacent wavelengths are set to 1 nm (number of wavelengths M=501). A threshold value is empirically determined by means of the function ϕ representing a matching degree, to thereby determine a copy. In the procedure, the threshold value is less than 3.5°, possibly 2.0°. The research conducted by the present inventors has empirically found that the matching degree function is greater than 3.5°, when any two layers of the three layers are exchanged. Thus, when the threshold value is set to be 3.5° or less, failure after exchange of layers can be detected. Further, the value of 2° is set in consideration of a safety factor.

### EXAMPLES

The present invention will next be described by way of examples.

The structure, formation, and analysis of the coating film according to the present invention are described.

### Example 1

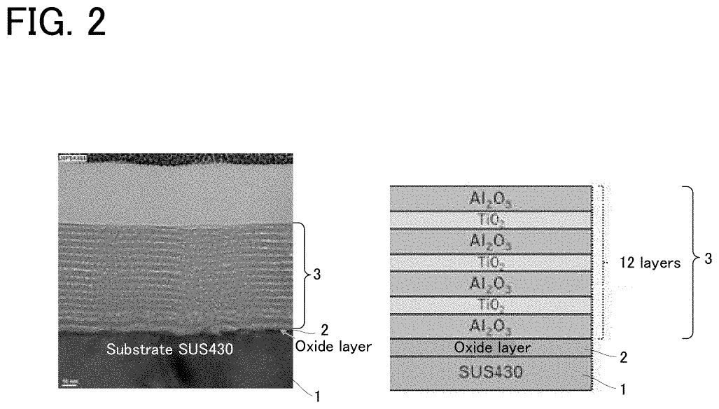

In Example 1, a coating film was formed on a substrate 1 made of a stainless steel plate (SUS430 material). This case is shown in FIG. 2. The coating film was formed through room-temperature atomic layer deposition.

FIG. 2 shows a cross-sectional TEM image of the films (FIG. 2(a)), and a schematic conceptual cross-section (FIG. 2(b)).

The film structure was formed by providing, on a stainless steel plate substrate, a metal oxide layer serving as an adhesion layer 2 by oxidizing the stainless steel plate substrate with plasma gas, and then forming thereon a moisture-proof layer 3 containing alumina as a predominant ingredient. The moisture-proof layer 3 containing alumina as a predominant ingredient was formed by alternatingly stacking 12 alumina layers and 12 TiO₂ layers and has a total thickness of 70 nm. The thickness of each alumina layer and that of each TiO₂ layer were 4 nm and 2 nm, respectively.

In Example 1, the raw material gases for forming and stacking alumina layers and TiO₂ layers were trimethylaluminum and tetrakis(dimethylamino)titanium, respectively. In the oxidation step for room-temperature atomic layer deposition, a plasma-excited humidified argon gas was used. The gas was prepared by bubbling pure water with pure argon at 60° C. for humidification of water, and generating plasma by a high-frequency magnetic field at 13.56 MHz provided by an RF coil.

Film formation was performed through the following procedure. In the case of forming alumina film, an aluminum sample to be coated was placed in a vacuum container, and trimethylaluminum was supplied to the vacuum container at about 200,000 Langmuire. Then, the vacuum container was evacuated for 30 seconds, and plasma-excited humidified argon plasma was supplied at 10 sccm for 2 minutes. Subsequently, the atmosphere of the container was discharged for 30 seconds, and the aforementioned procedure was repeated a predetermined number of times, to thereby perform film formation. In the case of forming titanium oxide film, tetrakis(dimethylamino)titanium was used instead of trimethylaluminum, under the same conditions.

In the TEM photoimage of FIG. 2 (2(a)), a dark grey portion of the moisture-proof layer 3 corresponds to alumina, and a white portion thereof corresponds to TiO₂ contained in the strain-relaxing layer. As is clear from the photoimage, no interlayer defoliation of the layer structure is observed. These stacked layers may be employed as an anti-corrosive film. If the substrate 1 is changed to a film, the film can be employed as a barrier film having a high water vapor penetration-inhibiting performance of 10⁻⁴ g/m²-day. The film may also be employed as a protective film for an organic EL device.

### Comparative Example 1

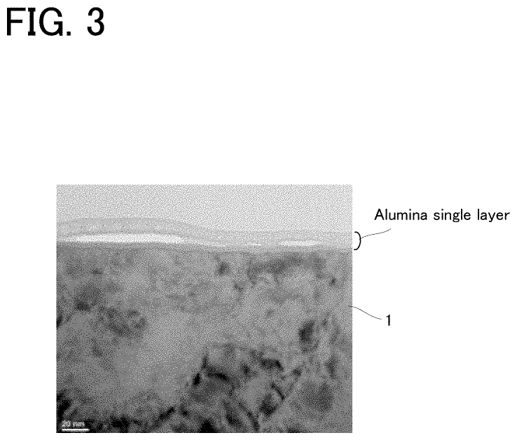

In Comparative Example 1 (vs. Example 1), an alumina film (20 nm) was directly formed on a substrate 1 made of stainless steel (SUS430) through room-temperature atomic layer deposition. FIG. 3 shows a TEM image thereof. The same film production method as employed in Example 1 was conducted. The obtained film was 20 nm, which was less than the thickness obtained in Example 1. However, local detachment of the film due to stress of the alumina film was observed, indicating occurrence of defoliation.

### Example 2

A substrate made of metallic aluminum was used. Alumina layers and carbon-containing alumina layers were alternatingly stacked through room-temperature atomic layer deposition to a total thickness of 70 nm. In Example 2, the adhesion layer was an aluminum oxide layer having a thickness of some nanometers formed of natural oxidation. The alternatingly stacked layers included 12 alumina layers (4 nm each) and 12 carbon-containing alumina layers (2 nm each).

The carbon-containing alumina layers were formed through room-temperature atomic layer deposition with a time of oxidation shortened to an about ¼ the reference time. As a result, the carbon content was elevated to about 15% to about 20%. In such a case, the carbon-containing alumina layer had a density lower than that of a pure alumina layer and inhibited propagation of film strain accumulated in pure alumina layers to an upper layer. Notably, in Example 2, no waterproof layer was provided.

### Comparative Example 2

The procedure of Example 2 was repeated, except that an alumina single layer was used instead of alumina-carbon-containing alumina alternatingly stacked layers. The alumina single layer had a film thickness of about 70 nm.

### Test Example 1

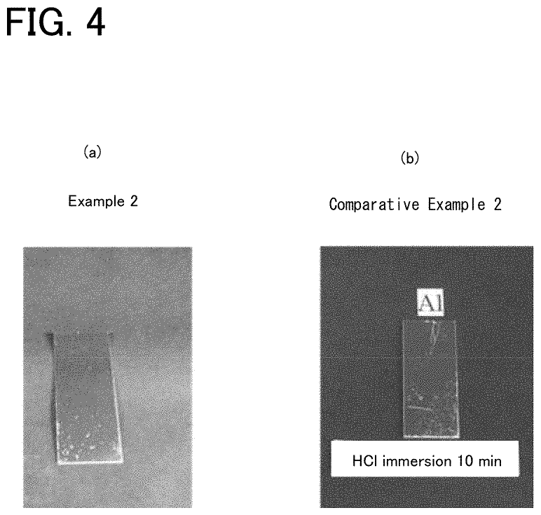

A sample of Example 2 and a sample of Comparative Example 2 were immersed in concentrated hydrochloric acid (35% mass %) at 22° C., and corrosion of the samples were observed. FIG. 4 shows the results.

Corrosion (stain) was observed after 15 minutes from the start of immersion for the alternatingly stacked layers of Example 2, but corrosion (stain) was observed after 10 minutes from the start of immersion for the alumina single layer of Comparative Example 2. Thus, a moisture-proof layer having an alternatingly stacked structure was found to have higher corrosion resistance to hydrochloric acid and higher film stability than those of a moisture-proof layer having a single layer structure.

### Example 3

A galvanized plate was used as a substrate. PMMA (acrylic resin film) was formed as the adhesion layer on the substrate. In a manner similar to that of Example 1, a moisture-proof layer mainly containing alumina was formed on the adhesion layer.

### Comparative Example 3

The procedure of Example 3 was repeated, except that no PMMA (acrylic resin film) was formed as the adhesion layer.

### Test Example 2

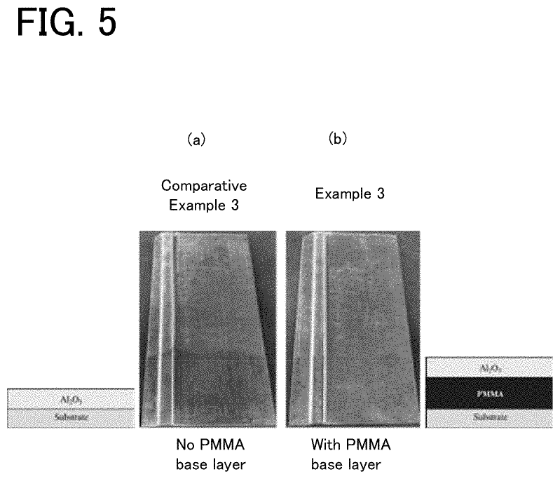

A sample of Example 3 and a sample of Comparative Example 3 were immersed in concentrated hydrochloric acid (35% mass %) for 60 seconds, and corrosion of the samples were observed. FIG. 5 shows the results.

No substantial corrosion was observed in the sample of Example 3, but corrosion was observed in the sample of Comparative Example 3.

Although the galvanized plate substrate per se had poor flatness, intervention of an adhesion layer made of PMMA between the substrate and the moisture-proof layer made of alumina conceivably flattened the surface of the substrate. Thus, conceivably, defoliation of the alumina moisture-proof layer was suppressed, and corrosion was inhibited.

### Example 4

In Example 4, a substrate made of stainless steel (SUS304) was used. The adhesion layer was formed from an oxide film, and an alumina single layer (15 nm) was formed through room-temperature atomic layer deposition. Subsequently, a PMMA resin layer (3 μm) was formed as the strain-relaxing layer. An alumina layer (15 nm) was formed thereon through room-temperature atomic layer deposition, to thereby provide a moisture-proof layer.

### Comparative Example 4

The procedure of Example 4 was repeated, except that no PMMA resin layer was provided as the adhesion layer.

### Test Example 3

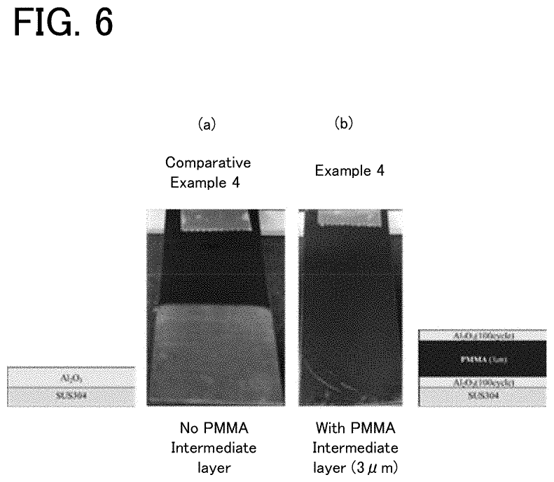

A sample of Example 4 and a sample of Comparative Example 4 were immersed in concentrated hydrochloric acid (35% mass %) for 20 minutes, and corrosion of the samples were observed. FIG. 6 shows the results.

After immersion in concentrated hydrochloric acid (35% mass %) for 20 minutes, corrosion was observed in the sample of Comparative Example 4. In contrast, corrosion did not proceed in the sample of Example 4 having an inserted strain-relaxing layer. Thus, the anti-corrosion performance of the coating film was found to be enhanced. Conceivably, PMMA mitigated the strain of the alumina layer, thereby suppressing defoliation of the film.

### Example 5

In Example 5, a laminated coating layer was produced by using a substrate made of stainless steel (SUS304), forming an alumina single layer (30 nm) on the substrate, and forming thereon a waterproof layer made of niobium oxide (Nb₂O₅) (5 nm). The adhesion layer was a natural oxide layer originating from SUS304.

### Comparative Example 5

The procedure of Example 5 was repeated, except that no niobium oxide (Nb₂O₅) layer was provided as the waterproof layer.

### Test Example 4

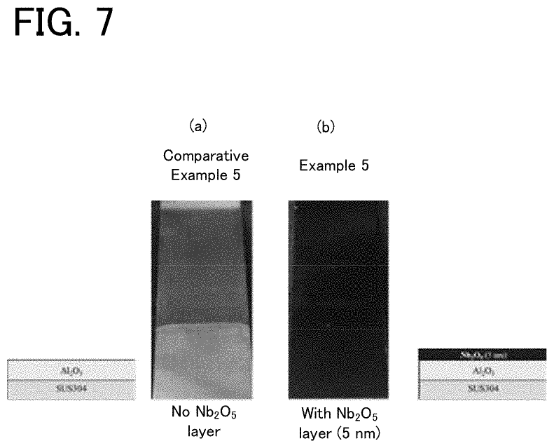

A sample of Example 5 and a sample of Comparative Example 5 were immersed in concentrated hydrochloric acid (35% mass %) for 30 minutes, and corrosion of the samples were observed. FIG. 7 shows the results.

As shown in FIG. 7, corrosion was observed in the sample of Comparative Example 5. In contrast, the sample of Example 5 having a niobium oxide waterproof surface layer (5 nm) was found to exhibit a clearly enhanced anti-corrosion performance to concentrated hydrochloric acid.

### Example 6

A laminated film structure was inspected. The laminated structure had a metal substrate made of iron, a TiO₂ adhesion layer (4 nm) formed on the substrate, an alumina moisture-proof layer (10 to 100 nm) formed thereon, and an SiO₂ waterproof layer (6.5 nm) formed thereon.

The surface of an analysis target was irradiated with S-polarized light and P-polarized light with the same amplitude at an incident angle of 75° with respect to the sample surface. The ratio in intensity of the reflected S-polarized light to the reflected P-polarized light, represented by tan ψ₁, and the phase difference between the reflected S-polarized light and the reflected P-polarized light, represented by Δ₁, were measured. Theoretical values of ψ₂ and Δ₂ were calculated within a range of 300 to 800 nm through a matrix method postulating the above laminated film structure. Whether or not the surface structure of the sample coincided with the above postulated structure was investigated through simulation on the basis of the coincidence of the measured ψ₁ and Δ₁ with the calculated ψ₂ and Δ₂.

Matching degree function ϕ was defined as follows, and a value of d_{A} (thickness of alumina film) which makes the function ϕ the minimum value was determined.

$$\begin{matrix}[ NF 3 ] & \\ ϕ = min χ ( {d}_{A} ) & ( 1 ) \\ χ ( {d}_{A} ) = {\frac{1}{\sqrt{2 M}} [ {\sum }_{i = 1}^{M} \{ {( {Δ}_{1} ( {λ}_{i} , {d}_{A} ) - {Δ}_{2} ( {λ}_{i} ) )}^{2} + {( {Ψ}_{1} ( {λ}_{i} , {d}_{A} ) - {Ψ}_{2} ( {λ}_{i} ) )}^{2} \} ]}^{1 / 2} & ( 2 )\end{matrix}$$

In the calculation, the wavelength λ₁ was set to 300 nm to 800 nm, and the intervals of adjacent wavelengths were set to 1 nm (number of wavelengths M=501).

The matching degree function was calculated when d_{A} was 10, 55, and 100 nm, and the ψ₂ and Δ₂ calculated through a matrix method were employed as the measured ψ₁ and Δ₁. Understandably, the matching degree function was 0. In this case, d_{A} completely coincided with the value postulated for the calculation, and there was no problem of varying d_{A} to a plurality of values (i.e., d_{A} was uniquely obtained). Thus, through employment of the spectral matching degree function, the film thickness of an alumina layer was correctly obtained. In addition, a 3-layer structure including a TiO₂ adhesion layer, alumina, and an SiO₂ layer, being sequentially stacked on the substrate, was successfully determined.

When the SiO₂ layer was exchanged with an Al₂O₃ layer in the above structure, the matching degree function ϕ was 3.58°. When the material of the Al₂O₃ layer was changed to HfO₂, the matching degree function ϕ was 21.1°. That is, when the two adjacent layers were mutually exchanged, or when the material of the alumina layer was changed, the matching degree function ϕ was the above-specified value. Thus, when the threshold value is set to be 3.5° or less (2.0° or less in consideration of safety), the sequence of TiO₂, alumina, and SiO₂ in the analyzed target was successfully determined.

### DESCRIPTION OF REFERENCE NUMERALS

1 substrate
2 adhesion layer
3 moisture-proof layer
4 waterproof layer

1. A laminated coating layer, which is a coating layer including a metal oxide film formed on a processing target through low-temperature atomic layer deposition, wherein the coating layer comprises at least one set of at least two layers of an adhesion layer, a moisture-proof layer, and a waterproof layer, stacked from the surface of the processing target in this order;
the adhesion layer is formed of at least one film selected from a metal oxide film and a resin film;
the moisture-proof layer is a film containing alumina as a predominant ingredient; and
the waterproof layer is formed of at least one film of a resin film and a metal oxide film which is selected from among a silica film, a niobium oxide film, and a zirconium oxide film.

2. The laminated coating layer according to claim 1, wherein the surface of the processing target is a hydrophilic surface, and the adhesion layer is formed of a silica film.

3. The laminated coating layer according to claim 1, wherein the surface of the processing target is a non-flat surface, and the adhesion layer is formed of the resin film.

4. The laminated coating layer according to claim 1, wherein the moisture-proof layer is a single layer of an alumina film having a thickness of 50 nm or less, or includes a structure in which an alumina film having a thickness of 50 nm or less and a strain-relaxing film are alternatingly and multiply stacked.

5. The laminated coating layer according to claim 4, wherein the strain-relaxing film is a film containing an oxide of a metal other than Group III metals, a film containing carbon as an impurity, or a resin film.

6. A method for forming a laminated coating layer as recited in claim 2, the method comprising
providing a vacuum container having a process container for accommodating a processing target; connecting, to the vacuum container, an exhaust means which can discharge the gas in the process container, an organometallic gas introduction means for introducing an organometallic gas into the process container and filling the container with the organometallic gas, and a humidified gas introduction means for introducing an excited and humidified gas into the process container and filling the container with the excited and humidified gas;
conducting the steps (1) to (4):
(1) a step of introducing the organometallic gas to the processing target through the organometallic gas introduction means;
(2) a step of discharging an organometallic gas surrounding the processing target through the exhaust means;
(3) a step of introducing the excited and humidified gas to the processing target through the excited and humidified gas introduction means; and
(4) a step of discharging the humidified gas surrounding the processing target through the exhaust means; and
repeating the steps (1) to (4), to thereby form the metal oxide film.

7. A method for determining a lamination structure, the method comprising irradiating the surface of a substrate provided with a laminated coating layer as recited in claim 1 with S-polarized light and P-polarized light with the same amplitude; measuring the ratio in intensity of the reflected S-polarized light to the reflected P-polarized light, represented by tan ψ, and the phase difference between the reflected S-polarized light and the reflected P-polarized light, represented by Δ, within a range of 300 to 800 nm, to thereby obtain ψ₁ and Δ₁; calculating theoretical values of ψ₂ and Δ₂ within a range of 300 to 800 nm through a matrix method on the basis of a postulated lamination structure with a variable d_{A} corresponding to the thickness of the moisture-proof layer; defining a function ϕ:
$$\begin{matrix}[ NF 1 ] & \\ ϕ = min χ ( {d}_{A} ) & ( 1 ) \\ χ ( {d}_{A} ) = {\frac{1}{\sqrt{2 M}} [ {\sum }_{i = 1}^{M} \{ {( {Δ}_{1} ( {λ}_{i} , {d}_{A} ) - {Δ}_{2} ( {λ}_{i} ) )}^{2} + {( {Ψ}_{1} ( {λ}_{i} , {d}_{A} ) - {Ψ}_{2} ( {λ}_{i} ) )}^{2} \} ]}^{1 / 2} & ( 2 )\end{matrix}$$
(wherein ϕ of formula (1) is a function for obtaining a minimum value of formula (2) with variation of d_{A}, and λᵢ is a wavelength of 300 nm to 800 nm in the calculation) as a function which can assess a matching degree between a measured value and a calculated value; and determining a threshold value by means of the function ϕ representing the matching degree, to thereby determine whether or not the laminated coating layer of the substrate has the postulated lamination structure.

8. A method for forming a laminated coating layer as recited in claim 3, the method comprising
providing a vacuum container having a process container for accommodating a processing target; connecting, to the vacuum container, an exhaust means which can discharge the gas in the process container, an organometallic gas introduction means for introducing an organometallic gas into the process container and filling the container with the organometallic gas, and a humidified gas introduction means for introducing an excited and humidified gas into the process container and filling the container with the excited and humidified gas;
conducting the steps (1) to (4):
(1) a step of introducing the organometallic gas to the processing target through the organometallic gas introduction means;
(2) a step of discharging an organometallic gas surrounding the processing target through the exhaust means;
(3) a step of introducing the excited and humidified gas to the processing target through the excited and humidified gas introduction means; and
(4) a step of discharging the humidified gas surrounding the processing target through the exhaust means; and
repeating the steps (1) to (4), to thereby form the metal oxide film.

9. The laminated coating layer according to claim 2, wherein the moisture-proof layer is a single layer of an alumina film having a thickness of 50 nm or less, or includes a structure in which an alumina film having a thickness of 50 nm or less and a strain-relaxing film are alternatingly and multiply stacked.

10. The laminated coating layer according to claim 3, wherein the moisture-proof layer is a single layer of an alumina film having a thickness of 50 nm or less, or includes a structure in which an alumina film having a thickness of 50 nm or less and a strain-relaxing film are alternatingly and multiply stacked.

11. A method for forming a laminated coating layer as recited in claim 4, the method comprising
providing a vacuum container having a process container for accommodating a processing target; connecting, to the vacuum container, an exhaust means which can discharge the gas in the process container, an organometallic gas introduction means for introducing an organometallic gas into the process container and filling the container with the organometallic gas, and a humidified gas introduction means for introducing an excited and humidified gas into the process container and filling the container with the excited and humidified gas;
conducting the steps (1) to (4):
(1) a step of introducing the organometallic gas to the processing target through the organometallic gas introduction means;
(2) a step of discharging an organometallic gas surrounding the processing target through the exhaust means;
(3) a step of introducing the excited and humidified gas to the processing target through the excited and humidified gas introduction means; and
(4) a step of discharging the humidified gas surrounding the processing target through the exhaust means; and
repeating the steps (1) to (4), to thereby form the metal oxide film.

12. A method for forming a laminated coating layer as recited in claim 5, the method comprising
providing a vacuum container having a process container for accommodating a processing target; connecting, to the vacuum container, an exhaust means which can discharge the gas in the process container, an organometallic gas introduction means for introducing an organometallic gas into the process container and filling the container with the organometallic gas, and a humidified gas introduction means for introducing an excited and humidified gas into the process container and filling the container with the excited and humidified gas;
conducting the steps (1) to (4):
(1) a step of introducing the organometallic gas to the processing target through the organometallic gas introduction means;
(2) a step of discharging an organometallic gas surrounding the processing target through the exhaust means;
(3) a step of introducing the excited and humidified gas to the processing target through the excited and humidified gas introduction means; and
(4) a step of discharging the humidified gas surrounding the processing target through the exhaust means; and
repeating the steps (1) to (4), to thereby form the metal oxide film.

13. A method for determining a lamination structure, the method comprising irradiating the surface of a substrate provided with a laminated coating layer as recited in claim 2 with S-polarized light and P-polarized light with the same amplitude; measuring the ratio in intensity of the reflected S-polarized light to the reflected P-polarized light, represented by tan ψ, and the phase difference between the reflected S-polarized light and the reflected P-polarized light, represented by Δ, within a range of 300 to 800 nm, to thereby obtain ψ₁ and Δ₁; calculating theoretical values of ψ₂ and Δ₂ within a range of 300 to 800 nm through a matrix method on the basis of a postulated lamination structure with a variable d_{A} corresponding to the thickness of the moisture-proof layer; defining a function ϕ:
$$\begin{matrix}[ NF 1 ] & \\ ϕ = min χ ( {d}_{A} ) & ( 1 ) \\ χ ( {d}_{A} ) = {\frac{1}{\sqrt{2 M}} [ {\sum }_{i = 1}^{M} \{ {( {Δ}_{1} ( {λ}_{i} , {d}_{A} ) - {Δ}_{2} ( {λ}_{i} ) )}^{2} + {( {Ψ}_{1} ( {λ}_{i} , {d}_{A} ) - {Ψ}_{2} ( {λ}_{i} ) )}^{2} \} ]}^{1 / 2} & ( 2 )\end{matrix}$$
(wherein ϕ of formula (1) is a function for obtaining a minimum value of formula (2) with variation of d_{A}, and λᵢ is a wavelength of 300 nm to 800 nm in the calculation) as a function which can assess a matching degree between a measured value and a calculated value; and determining a threshold value by means of the function ϕ representing the matching degree, to thereby determine whether or not the laminated coating layer of the substrate has the postulated lamination structure.

14. A method for determining a lamination structure, the method comprising irradiating the surface of a substrate provided with a laminated coating layer as recited in claim 3 with S-polarized light and P-polarized light with the same amplitude; measuring the ratio in intensity of the reflected S-polarized light to the reflected P-polarized light, represented by tan ψ, and the phase difference between the reflected S-polarized light and the reflected P-polarized light, represented by Δ, within a range of 300 to 800 nm, to thereby obtain ψ₁ and Δ₁; calculating theoretical values of ψ₂ and Δ₂ within a range of 300 to 800 nm through a matrix method on the basis of a postulated lamination structure with a variable d_{A} corresponding to the thickness of the moisture-proof layer; defining a function ϕ:
$$\begin{matrix}[ NF 1 ] & \\ ϕ = min χ ( {d}_{A} ) & ( 1 ) \\ χ ( {d}_{A} ) = {\frac{1}{\sqrt{2 M}} [ {\sum }_{i = 1}^{M} \{ {( {Δ}_{1} ( {λ}_{i} , {d}_{A} ) - {Δ}_{2} ( {λ}_{i} ) )}^{2} + {( {Ψ}_{1} ( {λ}_{i} , {d}_{A} ) - {Ψ}_{2} ( {λ}_{i} ) )}^{2} \} ]}^{1 / 2} & ( 2 )\end{matrix}$$
(wherein ϕ of formula (1) is a function for obtaining a minimum value of formula (2) with variation of d_{A}, and λᵢ is a wavelength of 300 nm to 800 nm in the calculation) as a function which can assess a matching degree between a measured value and a calculated value; and determining a threshold value by means of the function ϕ representing the matching degree, to thereby determine whether or not the laminated coating layer of the substrate has the postulated lamination structure.

15. A method for determining a lamination structure, the method comprising irradiating the surface of a substrate provided with a laminated coating layer as recited in claim 4 with S-polarized light and P-polarized light with the same amplitude; measuring the ratio in intensity of the reflected S-polarized light to the reflected P-polarized light, represented by tan ψ, and the phase difference between the reflected S-polarized light and the reflected P-polarized light, represented by Δ, within a range of 300 to 800 nm, to thereby obtain ψ₁ and Δ₁; calculating theoretical values of ψ₂ and Δ₂ within a range of 300 to 800 nm through a matrix method on the basis of a postulated lamination structure with a variable d_{A} corresponding to the thickness of the moisture-proof layer; defining a function ϕ:
$$\begin{matrix}[ NF 1 ] & \\ ϕ = min χ ( {d}_{A} ) & ( 1 ) \\ χ ( {d}_{A} ) = {\frac{1}{\sqrt{2 M}} [ {\sum }_{i = 1}^{M} \{ {( {Δ}_{1} ( {λ}_{i} , {d}_{A} ) - {Δ}_{2} ( {λ}_{i} ) )}^{2} + {( {Ψ}_{1} ( {λ}_{i} , {d}_{A} ) - {Ψ}_{2} ( {λ}_{i} ) )}^{2} \} ]}^{1 / 2} & ( 2 )\end{matrix}$$
(wherein ϕ of formula (1) is a function for obtaining a minimum value of formula (2) with variation of d_{A}, and λᵢ is a wavelength of 300 nm to 800 nm in the calculation) as a function which can assess a matching degree between a measured value and a calculated value; and determining a threshold value by means of the function ϕ representing the matching degree, to thereby determine whether or not the laminated coating layer of the substrate has the postulated lamination structure.

16. A method for determining a lamination structure, the method comprising irradiating the surface of a substrate provided with a laminated coating layer as recited in claim 5 with S-polarized light and P-polarized light with the same amplitude; measuring the ratio in intensity of the reflected S-polarized light to the reflected P-polarized light, represented by tan ψ, and the phase difference between the reflected S-polarized light and the reflected P-polarized light, represented by Δ, within a range of 300 to 800 nm, to thereby obtain ψ₁ and Δ₁; calculating theoretical values of ψ₂ and Δ₂ within a range of 300 to 800 nm through a matrix method on the basis of a postulated lamination structure with a variable d_{A} corresponding to the thickness of the moisture-proof layer; defining a function ϕ:
$$\begin{matrix}[ NF 1 ] & \\ ϕ = min χ ( {d}_{A} ) & ( 1 ) \\ χ ( {d}_{A} ) = {\frac{1}{\sqrt{2 M}} [ {\sum }_{i = 1}^{M} \{ {( {Δ}_{1} ( {λ}_{i} , {d}_{A} ) - {Δ}_{2} ( {λ}_{i} ) )}^{2} + {( {Ψ}_{1} ( {λ}_{i} , {d}_{A} ) - {Ψ}_{2} ( {λ}_{i} ) )}^{2} \} ]}^{1 / 2} & ( 2 )\end{matrix}$$
(wherein ϕ of formula (1) is a function for obtaining a minimum value of formula (2) with variation of d_{A}, and λᵢ is a wavelength of 300 nm to 800 nm in the calculation) as a function which can assess a matching degree between a measured value and a calculated value; and determining a threshold value by means of the function ϕ representing the matching degree, to thereby determine whether or not the laminated coating layer of the substrate has the postulated lamination structure.

17. A method for determining a lamination structure, the method comprising irradiating the surface of a substrate provided with a laminated coating layer as recited in claim 9 with S-polarized light and P-polarized light with the same amplitude; measuring the ratio in intensity of the reflected S-polarized light to the reflected P-polarized light, represented by tan ψ, and the phase difference between the reflected S-polarized light and the reflected P-polarized light, represented by Δ, within a range of 300 to 800 nm, to thereby obtain ψ₁ and Δ₁; calculating theoretical values of ψ₂ and Δ₂ within a range of 300 to 800 nm through a matrix method on the basis of a postulated lamination structure with a variable d_{A} corresponding to the thickness of the moisture-proof layer; defining a function ϕ:
$$\begin{matrix}[ NF 1 ] & \\ ϕ = min χ ( {d}_{A} ) & ( 1 ) \\ χ ( {d}_{A} ) = {\frac{1}{\sqrt{2 M}} [ {\sum }_{i = 1}^{M} \{ {( {Δ}_{1} ( {λ}_{i} , {d}_{A} ) - {Δ}_{2} ( {λ}_{i} ) )}^{2} + {( {Ψ}_{1} ( {λ}_{i} , {d}_{A} ) - {Ψ}_{2} ( {λ}_{i} ) )}^{2} \} ]}^{1 / 2} & ( 2 )\end{matrix}$$
(wherein ϕ of formula (1) is a function for obtaining a minimum value of formula (2) with variation of d_{A}, and λᵢ is a wavelength of 300 nm to 800 nm in the calculation) as a function which can assess a matching degree between a measured value and a calculated value; and determining a threshold value by means of the function ϕ representing the matching degree, to thereby determine whether or not the laminated coating layer of the substrate has the postulated lamination structure.

18. A method for determining a lamination structure, the method comprising irradiating the surface of a substrate provided with a laminated coating layer as recited in claim 10 with S-polarized light and P-polarized light with the same amplitude; measuring the ratio in intensity of the reflected S-polarized light to the reflected P-polarized light, represented by tan ψ, and the phase difference between the reflected S-polarized light and the reflected P-polarized light, represented by Δ, within a range of 300 to 800 nm, to thereby obtain ψ₁ and Δ₁; calculating theoretical values of ψ₂ and Δ₂ within a range of 300 to 800 nm through a matrix method on the basis of a postulated lamination structure with a variable d_{A} corresponding to the thickness of the moisture-proof layer; defining a function ϕ:
$$\begin{matrix}[ NF 1 ] & \\ ϕ = min χ ( {d}_{A} ) & ( 1 ) \\ χ ( {d}_{A} ) = {\frac{1}{\sqrt{2 M}} [ {\sum }_{i = 1}^{M} \{ {( {Δ}_{1} ( {λ}_{i} , {d}_{A} ) - {Δ}_{2} ( {λ}_{i} ) )}^{2} + {( {Ψ}_{1} ( {λ}_{i} , {d}_{A} ) - {Ψ}_{2} ( {λ}_{i} ) )}^{2} \} ]}^{1 / 2} & ( 2 )\end{matrix}$$
(wherein ϕ of formula (1) is a function for obtaining a minimum value of formula (2) with variation of d_{A}, and λᵢ is a wavelength of 300 nm to 800 nm in the calculation) as a function which can assess a matching degree between a measured value and a calculated value; and determining a threshold value by means of the function ϕ representing the matching degree, to thereby determine whether or not the laminated coating layer of the substrate has the postulated lamination structure.

19. A method for forming a laminated coating layer as recited in claim 9, the method comprising
providing a vacuum container having a process container for accommodating a processing target; connecting, to the vacuum container, an exhaust means which can discharge the gas in the process container, an organometallic gas introduction means for introducing an organometallic gas into the process container and filling the container with the organometallic gas, and a humidified gas introduction means for introducing an excited and humidified gas into the process container and filling the container with the excited and humidified gas;
conducting the steps (1) to (4):
(1) a step of introducing the organometallic gas to the processing target through the organometallic gas introduction means;
(2) a step of discharging an organometallic gas surrounding the processing target through the exhaust means;
(3) a step of introducing the excited and humidified gas to the processing target through the excited and humidified gas introduction means; and
(4) a step of discharging the humidified gas surrounding the processing target through the exhaust means; and
repeating the steps (1) to (4), to thereby form the metal oxide film.

20. A method for forming a laminated coating layer as recited in claim 10, the method comprising
providing a vacuum container having a process container for accommodating a processing target; connecting, to the vacuum container, an exhaust means which can discharge the gas in the process container, an organometallic gas introduction means for introducing an organometallic gas into the process container and filling the container with the organometallic gas, and a humidified gas introduction means for introducing an excited and humidified gas into the process container and filling the container with the excited and humidified gas;
conducting the steps (1) to (4):
(1) a step of introducing the organometallic gas to the processing target through the organometallic gas introduction means;
(2) a step of discharging an organometallic gas surrounding the processing target through the exhaust means;
(3) a step of introducing the excited and humidified gas to the processing target through the excited and humidified gas introduction means; and
(4) a step of discharging the humidified gas surrounding the processing target through the exhaust means; and
repeating the steps (1) to (4), to thereby form the metal oxide film.
